(19) United States
(12) Patent Application Publication
(10) Pub. No.: US 2021/0091143 A1
(43) Pub. Date: Mar. 25, 2021

(54) ORGANIC LIGHT EMITTING DIODE (OLED) TOUCH PANELS AND OLED TOUCH CONTROL DEVICES

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wenjie SHI, Shenzhen, Guangdong (CN)

(21) Appl. No.: 16/084,462

(22) PCT Filed: Feb. 12, 2018
(86) PCT No.: PCT/CN2018/076464

§ 371 Date: Sep. 12, 2018

(30) Foreign Application Priority Data
Dec. 29, 2017 (CN) 201711497860.0

(51) Int. Cl. H01L 27/32; G06F 3/041; H01L 51/52; G06F 3/044

(52) U.S. Cl. CPC H01L 27/323; G06F 3/0412; G06F 2203/04111; G06F 3/0445; G06F 2203/04107; H01L 51/5237

(57) ABSTRACT

The present disclosure relates to an organic light emitting diode (OLED) touch panel. The OLED touch panel includes an OLED display including a cathode and an encapsulation layer disposed on one side of the cathode layer, and a touch control layer disposed on the other side of the cathode. The touch control layer includes first electrode chains spaced apart from each other, second electrode chains spaced apart from each other, and first shielding electrode disposed between the first electrodes and the encapsulation layer. The first electrode chains include first electrodes electrically connected with each other. The second electrode chains include second electrodes electrically connected with each other, and the second electrodes and the first electrodes are disposed crossly and are insulated with each other. The first shielding electrode and the cathode form a first electric field to increase a mutual capacitance between the first electrodes and the second electrodes.

### CROSS REFERENCE TO RELATED APPLICATIONS

The present application claims the priority of China Application No. 201711497860.0, entitled “ORGANIC LIGHT EMITTING DIODE (OLED) TOUCH PANELS AND OLED TOUCH CONMOL DEVICES”, filed on Dec. 29, 2017, the disclosure of which is incorporated herein by reference in its entirety.

### BACKGROUND

### 1. Technical Field

The present disclosure generally relates to touch control technology field, and especially relates to an organic light emitting diode (OLED) touch panel and an OLED touch control device.

### 2. Description of Related Art

With the development of display technology, due that an organic light emitting diode (OLED) display panel is self-luminous without the need of the backlight, and has the advantages of high contrast, thin thickness, wide view angle, uniform resolution, and fast response, it is widely applied. When the OLED display panel is applied to a touch control device, after encapsulating the OLED display panel, the touch control module is then attached on the encapsulation structure of the OLED display panel. However, in the structure, the distance between the touch control module and the OLED display panel is closer, a cathode of the OLED display panel has the effect to driving signals of the touch control module, as so to lower a mutual capacitance of the touch control module, decreasing the sensibility of the touch control operation.

### SUMMARY

In one aspect, an organic light emitting diode (OLED) touch panel is provided. The OLED touch panel includes an OLED display layer and a touch control layer. The OLED displaying layer includes an cathode and an encapsulation layer disposed on one side of the cathode. The touch control layer is disposed on the other side of the cathode. The touch control layer includes a plurality of first electrode chains spaced apart from each other, a plurality of second electrode chains spaced apart from each other, and at least one first shielding electrode disposed between the first electrodes and the encapsulation layer. The first electrode chains include a plurality of first electrodes electrically connected with each other. The second electrode chains include a plurality of second electrodes electrically connected with each other, and the second electrodes and the first electrodes are disposed crossly and are insulated with each other. The first shielding electrode and the cathode are configured to form a first electric field to increase a mutual capacitance between the first electrodes and the second electrodes.

Comparing to the conventional technology, the OLED touch panel of the present disclosure provides the first shielding electrode disposed between the first electrodes and the encapsulation layer. The first shielding electrode and the cathode are configured to form a first electric field, reducing the effect of the cathode to the first electrodes, so as to increase a mutual capacitance between the first electrodes and the second electrodes 331, enhancing the sensibility of the touch control operation.

In another aspect, an OLED touch control device is provided. The OLED touch control device includes the OLED touch panel described above.

### BRIEF DESCRIPTION OF THE DRAWINGS

FIG. 1 is a schematic diagram of an organic lighting emitting diode (OLED) touch panel in accordance with first embodiment of the present disclosure.

FIG. 2 is a cross-sectional view taken along the line I-I of FIG. 1.

FIG. 3 is a schematic diagram of the OLED touch panel illustrating the distribution of electrical field lines in accordance with first embodiment of the present disclosure.

FIG. 4 is a schematic diagram the OLED touch panel in accordance with second embodiment of the present disclosure.

FIG. 5 is a cross-sectional view taken along the line II-II of FIG. 4.

FIG. 6 is a schematic diagram of the OLED touch panel illustrating the distribution of electrical field lines in accordance with second embodiment of the present disclosure.

FIG. 7 is a schematic diagram of adjacent first electrodes and second electrodes in the OLED touch panel in accordance with third embodiment of the present disclosure.

FIG. 8 is an exploded diagram of the first electrodes and the second electrodes of FIG. 7.

FIG. 9 is a schematic diagram of an OLED touch control device in accordance with first embodiment of the present disclosure.

### DETAILED DESCRIPTION

Following embodiments of the invention will now be described in detail hereinafter with reference to the accompanying drawings.

In the drawings, the thicknesses of layers and regions may be exaggerated for clarity. Same reference numerals refer to the same components throughout the specification and the drawings.

The above description is merely the embodiments in the present disclosure, the claim is not limited to the description thereby. The equivalent structure or changing of the process of the content of the description and the figures, or to implement to other technical field directly or indirectly should be included in the claim.

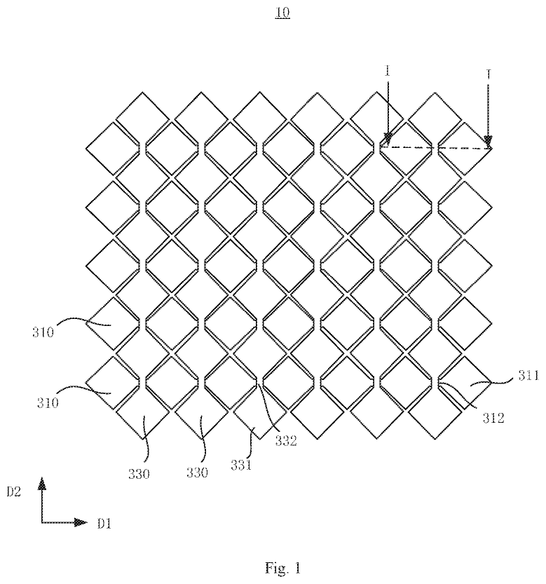

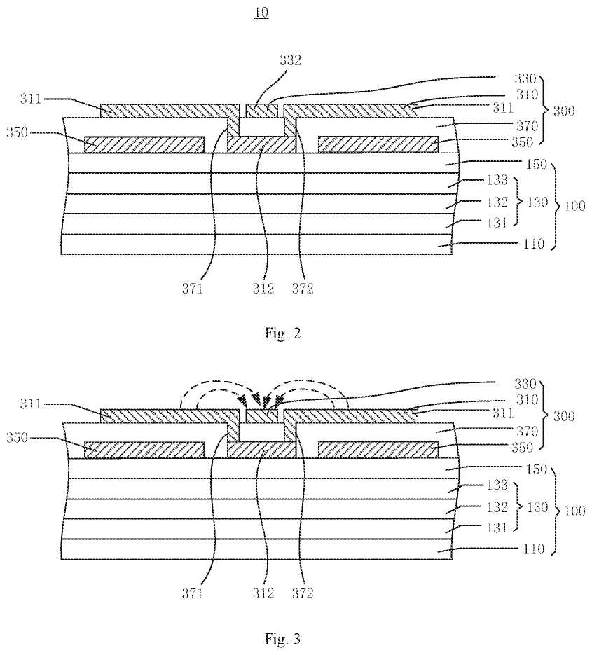

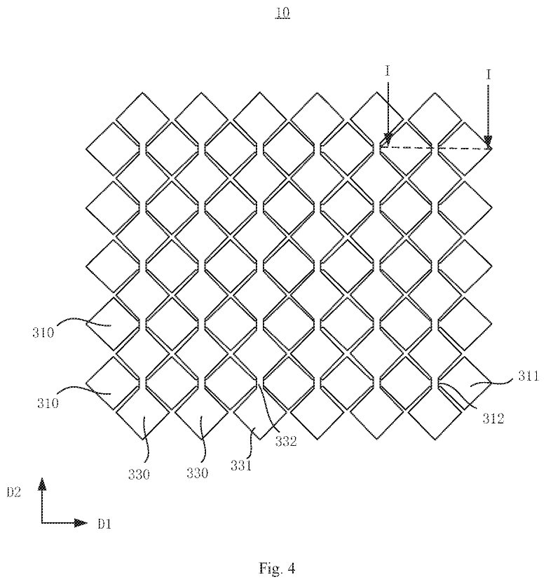

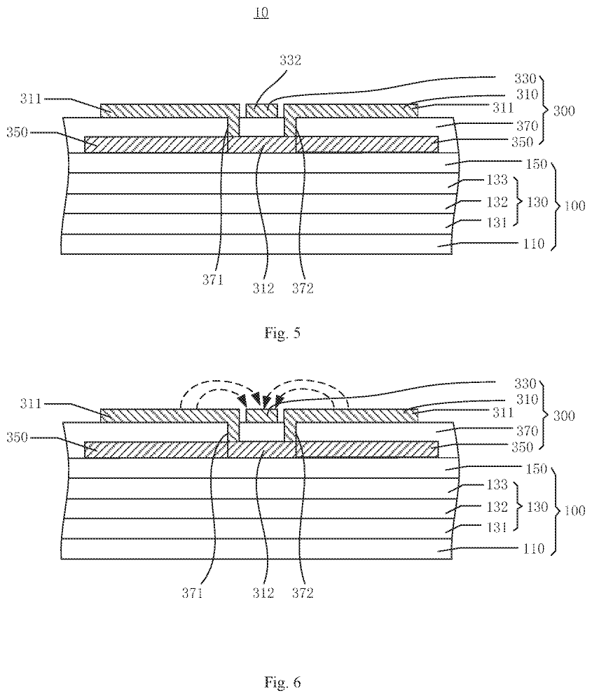

Referring to FIGS. 1 and 2, FIG. 1 is a schematic diagram of an organic lighting emitting diode (OLED) touch panel in accordance with one embodiment of the present disclosure, and FIG. 2 is a cross-sectional view taken along the line I-I of FIG. 1. The OLED touch panel 10 includes an OLED displaying layer 100 and a touch control layer 300. The OLED displaying layer 100 and the touch control layer 300 are stacked.

The OLED displaying layer 100 includes a cathode 133 and an encapsulation layer 150 disposed on one side of the cathode 133, and a touch control layer 300 disposed on the other side of the cathode. The touch control layer 300 includes a plurality of first electrode chains 310 spaced apart from each other, a plurality of second electrode chains 330 spaced apart from each other, and at least one first shielding electrode 350. The first electrode chains 310 includes a plurality of first electrode 311 electrically connected with each other. The second electrode chains 330 includes a plurality of second electrode 331 electrically connected with each other, and the second electrodes 331 and the first electrodes 311 are disposed crossly and are insulated with each other. The first shielding electrode 350 is disposed between the first electrodes 311 and the encapsulation layer 150. The first shielding electrode 350 and the cathode 133 are configured to form a first electric field to increase a mutual capacitance between the first electrodes 311 and the second electrodes 331.

Specifically, the OLED displaying layer 100 includes a thin film transistor (TFT) layer 110, a light emitting layer 130 and an encapsulation layer 150 that are sequentially stacked. The TFT layer 110 includes a plurality of TFTs arranged in a matrix. The TFTs are configured to control the lighting of the light emitting layer 130. Specifically, the light emitting layer 130 includes an anode 131, a luminescent material layer 132, and a cathode 133 that are stacked. The anode 131 is electrically connected with the TFTs (usually drains of the TFTs), to receive first control signals of the TFTs. The first control signals are configured to control the anode 131 to provide holes. The cathode 133 is applied with second control signals. The second control signals are configured to control the anode 133 to provide electrons. The holes provided by the anode 131 and the electrons provided by the cathode 133 are combined within the luminescent material layer 132 to emit light. In one embodiment, the first control signals are positive voltages, and the second control signals are negative voltages.

The first shielding electrode 350 is disposed between the first electrodes 311 and the encapsulation layer 150. The first shielding electrode 350 and the cathode 133 are configured to form a first electric field, reducing the effect of the cathode 133 to the first electrodes 311, so as to increase a mutual capacitance between the first electrodes 311 and the second electrodes 331, enhancing the sensibility of the touch control operation.

In one embodiment, the first shielding electrode 350 is applied with the first voltage, the first electrodes 311 are applied with a second voltage, and a polarity of the second voltage and the polarity of the first voltage are the same. Preferably, an amplitude of the second voltage and the amplitude of the first voltage are the same. By applying the first voltage to the first shielding electrode 350, applying the second voltage to the first electrode 311, and the polarity of the second voltage and the polarity of the first voltage being the same, such that the electric field lines between the first shielding electrode 350 and the first electrode 311 are repulsive to each other, so as to provide the electric field lines of the first electrodes 311 more coupling with the second electrodes 331 (referring to FIG. 6), to increase a mutual capacitance between the first electrodes 311 and the second electrodes 331, so as to enhance the sensibility of the touch control operation. Furthermore, when the amplitude of the second voltage and the amplitude of the first voltage are the same, the electric field lines between the first shielding electrode 350 and the first electrode 311 are totally repulsive to each other, so as to provide the electric field lines of the first electrodes 311 optimally coupling with the second electrodes 331 (referring to FIG. 6), to further increase a mutual capacitance between the first electrodes 311 and the second electrodes 331, so as to further enhance the sensibility of the touch control operation.

In one embodiment, the first electrodes 311 and the first shielding electrode 350 are connected to the same signal line, to receive the same voltage.

The first electrode chains 310 further includes a first connecting member 312. The first connecting member 312 and the first shielding electrode 350 are disposed on the side away from the cathode 133, and the first connecting member 312 and the first shielding electrode 350 are disposed within the same layer. The difference between the embodiment and the above embodiment is that the first connecting member 312 and the first shielding electrode 350 are disposed within the same layer, and the first connecting member 312 is connected with the first shielding electrode 350. In other words, the first connecting member 312 is connected with the first shielding electrode 350 to form an integral structure. In one embodiment, the first connecting member 312 and the first shielding electrode 350 are disposed within the same layer and are made by the same material. For example, the first connecting member 312 and the first shielding electrode 350 are made by the same transparent material or metal material. The first connecting member 312 and the first shielding electrode 350 also can be made by the same manufacturing process, to save the process.

Correspondingly, the touch control layer 300 further incudes an insulating layer 370 covering the first connecting member 312 and the first shielding electrode 350. The insulating layer 370 comprises a first through hole 371 and a second through hole 372 spaced apart from each other. The first through hole 371 and the second through hole 372 are respectively configured to expose a portion of the first connecting member 312.

The first electrodes 311 are disposed on a surface of the encapsulation layer 370 facing away the insulating layer 150, and two adjacent first electrodes 311 are electrically connected with the first connecting member 312 via the first through hole 371 and the second through hole 372, respectively. In other words, the first connecting member 312 is configured to electrically connect two adjacent first electrodes 311. In one embodiment, the first connecting member 312 and the first shielding electrode 350 are disposed within the same layer and are made by the same material. For example, the first connecting member 312 and the first shielding electrode 350 are made by the same transparent material or metal material. The first connecting member 312 and the first shielding electrode 350 also can be made by the same manufacturing process, to save the process.

Correspondingly, the second electrode chains further includes a second connecting member 332. The second connecting member 332 is configured to electrically connect two adjacent second electrodes 331. The second connecting member 332 is disposed on a surface of the first connecting member 312 facing away the insulating layer 370, and the second connecting member 332 is disposed corresponding to the first connecting 312.

Preferably, a projection of the first electrodes 311 on the encapsulation layer 150 is a first projection, the projection of the first shielding electrode 350 on the encapsulation layer 150 is a second projection, and the first projection at least partially overlap with the second projection. Preferably, the first projection is within the second projection. By the projection of the first electrodes 311 on the encapsulation layer 150 being within the projection of the first shielding electrode 350 on the encapsulation layer 150, the first shielding electrode 350 shields the effect of the cathode 133 to the first electrodes 311 better, so as to provide the electric field lines of the first electrodes 311 optimally coupling with the second electrodes 331, to further increase a mutual capacitance between the first electrodes 311 and the second electrodes 331, so as to further enhance the sensibility of the touch control operation.

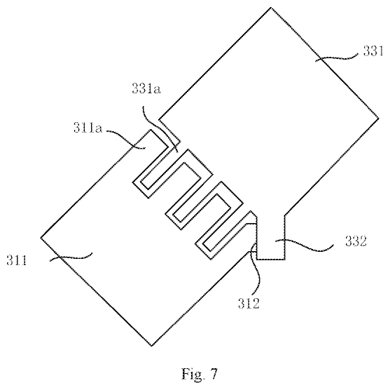

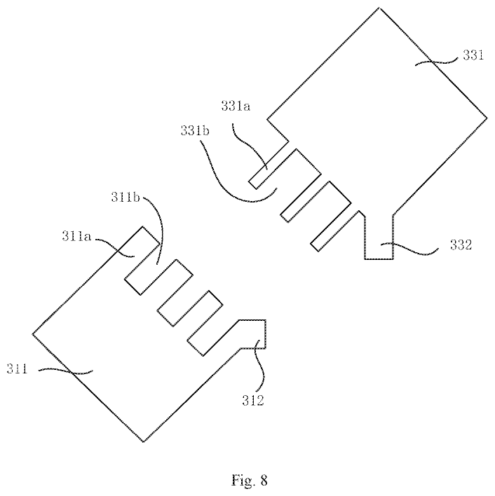

Furthermore, referring to FIGS. 7 and 8, the first electrodes 311 include a plurality of first branches 311a spaced apart from each other. A second gap 311b is formed between two adjacent first branches 311a. The second electrodes 331 include a plurality of second branches 331a spaced apart from each other. A third gap 331b is formed between two adjacent second branches 331a. The second branch 331a is disposed within the second gap 311b and the first branch 311a, is disposed within the third gap 331b.

The first electrodes 311 include a plurality of first branches 311a spaced apart from each other. By the second electrodes 331 including the second branches 331a spaced apart from each other, the first branch 311a being disposed within the third gap 331b formed between two adjacent second electrodes 331, and the second branches 331a being disposed within the second gap 311b formed between two adjacent first branches 311a, to further increase a mutual capacitance between the first electrodes 311 and the second electrodes 331, so as to further enhance the sensibility of the touch control operation.

In one embodiment, the first electrodes 311 are emitting electrodes, also called driving electrodes. The second electrodes 331 are receiving electrodes, also called sensing electrodes. In another embodiment, the first electrodes 311 are receiving electrodes, and the second electrode 331 are emitting electrodes. The first electrode 311 and the second electrode 331 may be made to a block structure by a transparent material, or may be made to a cell structure by a metal material. The outline of the first electrodes 311 and the second electrode 331 may be, but not limited to, a diamond outline, a square outline, or rectangle outline.

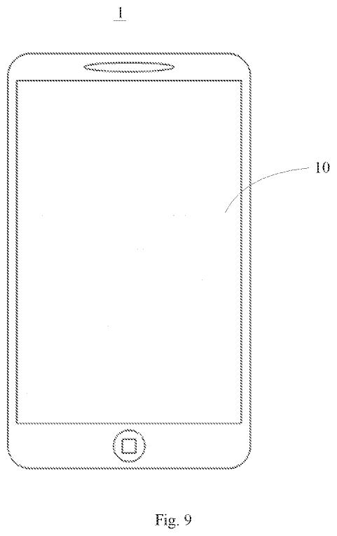

The present disclosure further provides an OLED touch control device. Referring to FIG. 9, FIG. 9 is a schematic diagram of an OLED touch control device in accordance with one embodiment of the present disclosure. The OLED touch control device 1 includes the OLED touch panel 10 in any one of the embodiment described above, and being omitted herein. The touch control device may be, but not limited to, a E-book, a smart phone (e.x. Android cellphone, iOS cellphone, Window Phone cellphone), a tablet, a cellphone, a notebook, a mobile interact device (MID), or ahead-wear device.

In another embodiment, a display is provided. The display uses the backlight module. The backlight module uses the QD LED as a backlight source. The detailed description of the QD LED can be referred the description in FIG. 2, and is omitted herein.

In view of the above, the present disclosure uses quantum dots (QDs) to be a package of the optical fiber, so as to provide the QD the environment of low oxygen permeability, low water permeability, and high heat conductivity, such that the QD can provide high emitting efficiency.

For the skilled in the art, it is clear that the disclosure is not limited to the details of an exemplary embodiment. And without departing from the spirit or essential characteristics of the present disclosure, it is possible to realize the disclosure with other specific forms. Therefore, no matter with any points, it should be seen as an exemplary embodiment, but not limiting, the scope of the present disclosure is defined by the appended claims rather than the foregoing description define, and therefore intended to fall claim All changes which come within the meaning and range of equivalents of the elements to include in the present invention.

1. An organic light emitting diode (OLED) touch panel, comprising:
an OLED displaying layer, comprising a cathode and an encapsulation layer disposed on one side of the cathode; and
a touch control layer disposed on the other side of the cathode, the touch control layer comprising;
a plurality of first electrode chains spaced apart from each other, the first electrode chains comprising a plurality of first electrodes electrically connected with each other;
a plurality of second electrode chains spaced apart from each other, the second electrode chains comprising a plurality of second electrodes electrically connected with each other, and the second electrodes and the first electrodes being disposed crossly and being insulated with each other; and
at least one first shielding electrode disposed between the first electrodes and the encapsulation layer, the at least one first shielding electrode and the cathode being configured to form a first electric field to increase a mutual capacitance between the first electrodes and the second electrodes;
wherein the cathode of the OLED displaying layer is disposed under the encapsulation layer and the at least one first shielding electrode is disposed on the encapsulation layer, and the at least one first shielding electrode is between the cathode and the first electrodes to shield the first electrodes from the cathode.

2. The OLED touch panel as claimed in claim 1, wherein the at least one first shielding electrode is applied with a first voltage, the first electrodes are applied with a second voltage, and a polarity of the second voltage and the polarity of the first voltage are the same.

3. The OLED touch panel as claimed in claim 2, wherein an amplitude of the second voltage and the amplitude of the first voltage are the same.

4. The OLED touch panel as claimed in claim 3, wherein the first electrodes and the at least one first shielding electrode are connected to the same signal line, to receive the same voltage.

5. The OLED touch panel as claimed in claim 1, wherein:
the first electrode chains further comprise a first connecting member; the first connecting member and the at least one first shielding electrode are disposed on the side away from the cathode, and the first connecting member and the at least one first shielding electrode are disposed within the same layer;
the touch control layer further comprises an insulating layer covering the first connecting member and the at least one first shielding electrode; the insulating layer comprises a first through hole and a second through hole spaced apart from each other, the first through hole and the second through hole are respectively configured to expose a portion of the first connecting member; and
the first electrodes are disposed on a surface of the encapsulation layer facing away the insulating layer, and two adjacent first electrodes are electrically connected with the first connecting member via the first through hole and the second through hole, respectively.

6. The OLED touch panel as claimed in claim 5, wherein the first connecting member is connected with the at least one first shielding electrode.

7. The OLED touch panel as claimed in claim 5, wherein a first gap is configured between the first connecting member and the at least one first shielding electrode.

8. The OLED touch panel as claimed in claim 7, wherein a projection of the first electrodes on the encapsulation layer is a first projection, the projection of the at least one first shielding electrode on the encapsulation layer is a second projection, and the first projection at least partially overlaps with the second projection.

9. The OLED touch panel as claimed in claim 1, wherein the first electrodes comprise a plurality of first branches spaced apart from each other, a second gap is formed between two adjacent first branches; the second electrodes comprise a plurality of second branches spaced apart from each other, a third gap is formed between two adjacent second branches; the second branch is disposed within the second gap and the first branch is disposed within the third gap.

10. An organic light emitting diode (OLED) touch control device, the OLED touch control device comprising an OLED touch panel, the OLED touch panel comprising:
an OLED displaying layer, comprising a cathode and an encapsulation layer disposed on one side of the cathode; and
a touch control layer disposed on the other side of the cathode, the touch control layer comprising;
a plurality of first electrode chains spaced apart from each other, the first electrode chains comprising a plurality of first electrodes electrically connected with each other;
a plurality of second electrode chains spaced apart from each other, the second electrode chains comprising a plurality of second electrodes electrically connected with each other, and the second electrodes and the first electrodes being disposed crossly and being insulated with each other; and
at least one first shielding electrode disposed between the first electrodes and the encapsulation layer, the at least one first shielding electrode and the cathode being configured to form a first electric field to increase a mutual capacitance between the first electrodes and the second electrodes;
wherein the cathode of the OLED displaying layer is disposed under the encapsulation layer and the at least one first shielding electrode is disposed on the encapsulation layer, and the at least one first shielding electrode is between the cathode and the first electrodes to shield the first electrodes from the cathode.

11. The OLED touch control device as claimed in claim 10, wherein the at least one first shielding electrode is applied with a first voltage, the first electrodes are applied with a second voltage, and a polarity of the second voltage and the polarity of the first voltage are the same.

12. The OLED touch control device as claimed in claim 11, wherein an amplitude of the second voltage and the amplitude of the first voltage are the same.

13. The OLED touch control device as claimed in claim 12, wherein the first electrodes and the at least one first shielding electrode are connected to the same signal line, to receive the same voltage.

14. The OLED touch control device as claimed in claim 10, wherein:
the first electrode chains further comprise a first connecting member; the first connecting member and the at least one first shielding electrode are disposed on the side away from the cathode, and the first connecting member and the at least one first shielding electrode are disposed within the same layer;
the touch control layer further comprises an insulating layer covering the first connecting member and the at least one first shielding electrode; the insulating layer comprises a first through hole and a second through hole spaced apart from each other, the first through hole and the second through hole are respectively configured to expose a portion of the first connecting member; and
the first electrodes are disposed on a surface of the encapsulation layer facing away the insulating layer, and two adjacent first electrodes are electrically connected with the first connecting member via the first through hole and the second through hole, respectively.

15. The OLED touch control device as claimed in claim 14, wherein the first connecting member is connected with the at least one first shielding electrode.

16. The OLED touch control device as claimed in claim 14, wherein a first gap is configured between the first connecting member and the at least one first shielding electrode.

17. The OLED touch control device as claimed in claim 16, wherein a projection of the first electrodes on the encapsulation layer is a first projection, the projection of the at least one first shielding electrode on the encapsulation layer is a second projection, and the first projection at least partially overlaps with the second projection.

18. The OLED touch control device as claimed in claim 10, wherein the first electrodes comprise a plurality of first branches spaced apart from each other, a second gap is formed between two adjacent first branches; the second electrodes comprise a plurality of second branches spaced apart from each other, a third gap is formed between two adjacent second branches; the second branch is disposed within the second gap and the first branch is disposed within the third gap.
